(19) United States
(12) Patent Application Publication
(10) Pub. No.: US 2012/0032566 A1
(43) Pub. Date: Feb. 9, 2012

(54) HOUSING AND FABRICATION METHOD THEREOF

(75) Inventors: SHYAN-JUH LIU, Tu-Cheng (TW); YEN-TAI LIN, Tu-Cheng (TW); SHA-SHA LIU, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 12/913,971

(22) Filed: Oct. 28, 2010

(30) Foreign Application Priority Data
Aug. 3, 2010 (CN) 201010241999.0

(51) Int. Cl. H05K 5/02; B29C 67/24; B82Y 30/00; B82Y 40/00

(52) U.S. Cl. 312/223.1; 264/259; 264/482; 977/700; 977/889

(57) ABSTRACT

A housing includes a main body having an interface and a plastic portion molded on the interface. The main body defines a nanostructure in the interface. The nanostructure includes a plurality of regular, repeating units. A pitch between the adjacent units is in the range from 10 nanometers to 500 nanometers. A height of each unit is in the range from 10 nanometers to 100 nanometers. A surface roughness of the nanostructure is in the range from 1 nanometer to 10 nanometers.

### BACKGROUND

1. Technical Field

The present disclosure relates to device housings, and particularly, to a housing having a nanostructure and a fabrication method thereof.

2. Description of the Related Art

Metal and plastic, due to their water resistance, corrosion resistance and mechanical properties, are widely used in electronic devices. A common housing of an electronic device includes a metal body, an adhesive layer and a plastic portion. The adhesive layer is sandwiched between the metal body and the plastic portion, such that the plastic portion is fixed to the metal body. However, bonding strength between the metal body and the plastic portion decreases with time.

Therefore, there is room for improvement within the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views, and all the views are schematic.

FIG. 1 is a cross-section of one embodiment of a housing.

FIG. 2 is an enlarged view of a circled portion II shown in FIG. 1.

FIG. 3 is a flowchart of a fabrication method of the housing shown in FIG. 1.

### DETAILED DESCRIPTION

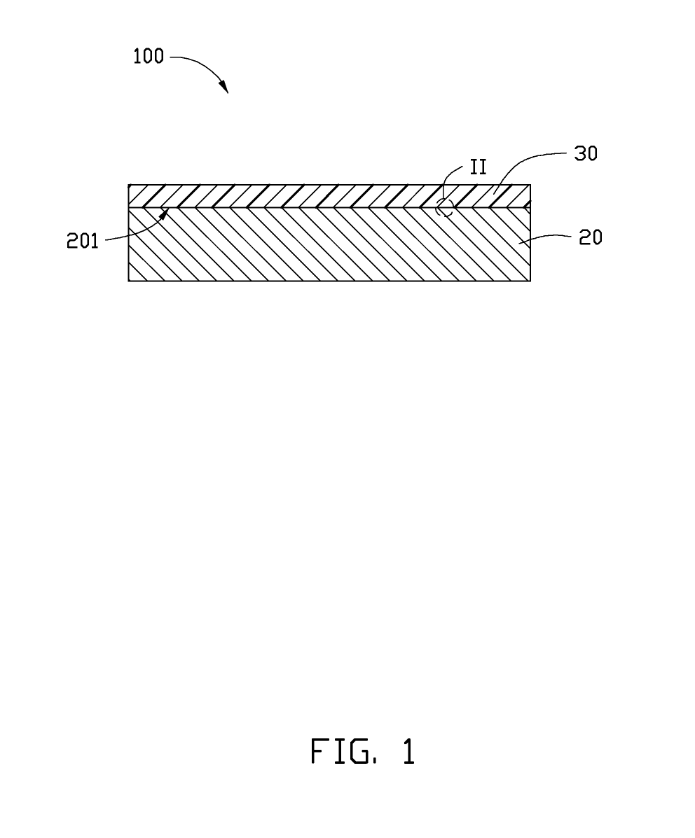

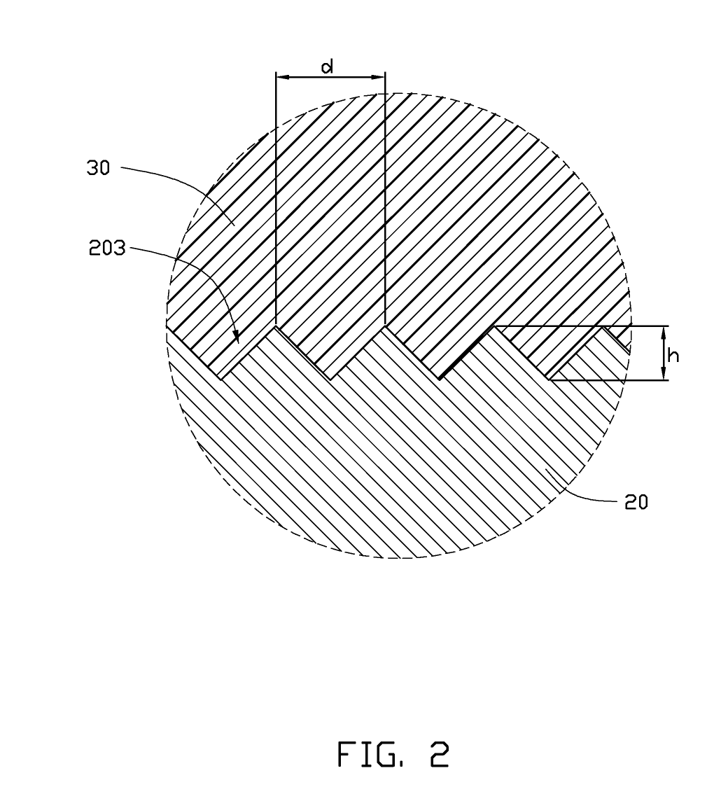

Referring to FIGS. 1 and 2, one embodiment of a housing 100 includes a main body 20 and a plastic portion 30 integrally formed with the main body 20. The main body 20 and the plastic portion 30 can be formed in different structures. For example, the main body 20 can be a conducting sheet of a mobile phone, and the plastic portion 30 can be a battery housing of a mobile phone.

The main body 20 can be glass, metal, alloy, ceramic or enamel such as magnesium, aluminum, or iron. The alloy may be magnesium alloy or aluminum alloy.

The main body 20 includes an interface 201 contacting the plastic portion 30 and a nanostructure 203 formed in the interface 201. The nanostructure 203 is a plurality of regular, repeating units. In the illustrated embodiment, each regular repeating unit is a sawtooth-shaped ridge. A pitch d between adjacent ridges is in the range from 10 nanometers to 500 nanometers. A height h of each ridge is in the range from 10 nanometers to 100 nanometers. A surface roughness of the nanostructure 203 is in the range from 1 nanometer to 10 nanometers. The plastic portion 30 is partially received in the nanostructure 203, such that the plastic portion 30 is firmly formed and attached with the main body 20.

In the illustrated embodiment, the nanostructure 203 is directly formed as part of the interface 201 of the main body 20, which reduces a contact angle of water droplets to a smaller contact angle. Thus, the interface 201 of the main body 20 can remain hydrophilic for a longer time, and enhances bonding strength between the main body 20 and the plastic portion 30. Furthermore, the nanostructure 203 is much smaller in size compared with the main body 20 as a whole, which is typically macroscopic in size. Therefore, the nanostructure 203 does not change the overall shape of the main body 20, and does not affect the original appearance of the main body 20. In addition, the main body 20 is connected to the plastic portion 30 without hook structures, such that the housing 100 is easily made to be more and more thinner.

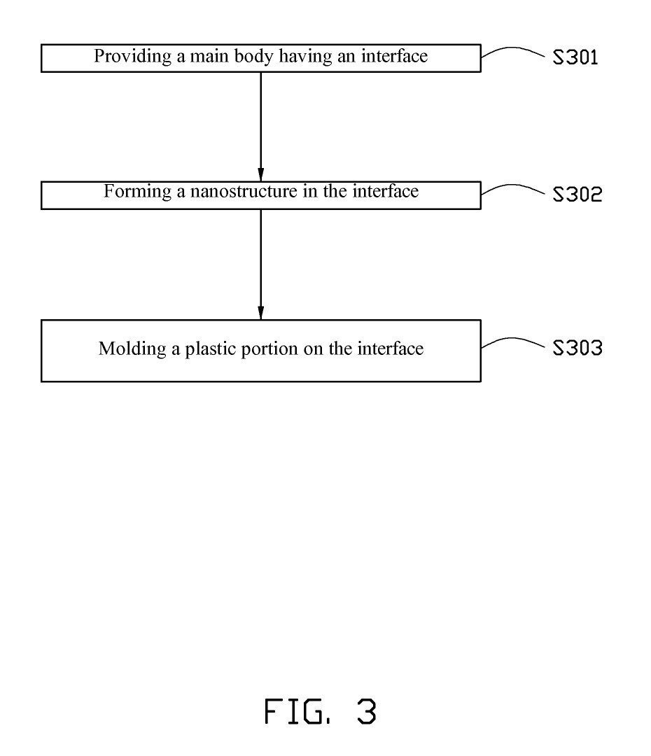

Referring to FIG. 3, a fabrication method 100 of the present disclosure is illustrated as follows.

In step S301, a main body 20 is provided. An interface 201 is defined in a side surface of the main body 20.

In step S302, the nanostructure 203 is formed in the interface 201. In the illustrated embodiment, the nanostructure 203 is formed in the interface 201 by a laser method.

The laser method for the hydrophilic treatment of the nanostructure 203 includes the following steps: providing a material having a surface (step 1); providing a laser source (step 2); and applying a plurality of laser beams produced by the laser source to the interface 201 of the main body 20 to form a hydrophilic nanostructure (step 3). In step 1, the material of the main body 20 may be glass, metal, an alloy, ceramic or enamel. The particular laser source employed varies according to the material of the main body 20 provided. If the material is glass, a carbon dioxide laser is employed to process the glass surface. If the material is a metal or an alloy, a neodymium doped yttrium aluminum garnet (Nd:YAG) laser or a femtosecond laser is employed to process the metal or alloy surface. Applying the laser beams to the material surface involves well-known laser processing or laser-carving technologies. That is, high-intensity laser beams produced by the laser source are focused on the surface of the material to form a predetermined shape in the surface, all of which is controlled by a computer. The power density of the focused laser beams can be between 10⁷-10¹² watts per square centimeter, and the temperature of the surface can be up to 1×10⁵ degrees Celsius. Accordingly, virtually any glass, metal or alloy material can be fused and vaporized immediately.

In step S303, the plastic portion 30 is molded on the interface 203 of the main body 20 by insert molding. The main body 20 is placed into a mold. Molten plastic material is injected on the interface 203. After the molten plastic material is solidified, the plastic portion 30 is firmly formed in the interface 203 of the main body 20.

It should be noted that the nanostructure 203 may also be a plurality of regular, repeating units having other shapes. For example, each repeating unit may be a ridge that is hump-shaped, square-shaped, step-shaped, or multi-step-shaped. The nanostructure 203 may also be defined in a portion of the interface 201.

Finally, while the present disclosure has been described with reference to particular embodiments, the description is illustrative of the disclosure and is not to be construed as limiting the disclosure. Therefore, various modifications can be made to the embodiments by those of ordinary skill in the art without departing from the true spirit and scope of the disclosure as defined by the appended claims.

What is claimed is:

1. A housing comprising:
a main body having an interface; and
a plastic portion molded on the interface, wherein the main body defines a nanostructure in the interface.

2. The housing of claim 1, wherein the nanostructure comprises a plurality of regular, repeating units.

3. The housing of claim 2, wherein a pitch between the adjacent units is in the range from 10 nanometers to 500 nanometers.

4. The housing of claim 2, wherein a height of each unit is in the range from 10 nanometers to 100 nanometers.

5. The housing of claim 2, wherein each unit is sawtooth-shaped, hump-shaped, square-shaped, step-shaped, or multi-step-shaped.

6. The housing of claim 1, wherein a surface roughness of the nanostructure is in the range from 1 nanometer to 10 nanometers.

7. The housing of claim 1, wherein the material of the main body is selected from the group consisting of glass, metal and an alloy.

8. A fabrication method of a housing comprising:
providing a main body having an interface;
forming a nanostructure in the interface; and
molding a plastic portion on the interface.

9. The fabrication method of the housing of claim 8, wherein the nanostructure is formed in the interface by a laser source.

10. The fabrication method of the housing of claim 9, wherein the laser source is a carbon dioxide laser.

11. The fabrication method of the housing of claim 9, wherein the laser source is a neodymium doped yttrium aluminum garnet laser or a femtosecond laser.

12. The fabrication method of the housing of claim 8, wherein the nanostructure comprises a plurality of regular, repeating units.

13. The fabrication method of the housing of claim 12, wherein a pitch between adjacent repeating units is in the range from 10 nanometers to 500 nanometers.

14. The fabrication method of the housing of claim 12, wherein a height of each repeating unit is in the range from 10 nanometers to 100 nanometers.

15. The fabrication method of the housing of claim 12, wherein each repeating unit is sawtooth-shaped, hump-shaped, square-shaped, step-shaped, or multi-step-shaped.

16. The fabrication method of the housing of claim 8, wherein a surface roughness of the nanostructure is in the range from 1 nanometer to 10 nanometers.

17. The fabrication method of the housing of claim 8, wherein the material of the main body is selected from the group consisting of glass, metal and an alloy.
